(19) United States
(12) Patent Application Publication
(10) Pub. No.: US 2025/0318053 A1
(43) Pub. Date: Oct. 9, 2025

(54) ELECTRONIC DEVICE AND METHOD FOR MANUFACTURING ELECTRONIC DEVICE

(71) Applicant: Rohm Co., Ltd., Kyoto-shi (JP)

(72) Inventor: Hiroyuki SHINKAI, Kyoto-shi (JP)

(21) Appl. No.: 19/243,981

(22) Filed: Jun. 20, 2025

Related U.S. Application Data
(63) Continuation of application No. PCT/JP2023/044243, filed on Dec. 11, 2023.

(30) Foreign Application Priority Data
Dec. 28, 2022 (JP) 2022-211093

(51) Int. Cl. H05K 1/18; H05K 1/09; H05K 3/06; H05K 3/28; H05K 3/30; H05K 3/34

(52) U.S. Cl. CPC H05K 1/181; H05K 1/09; H05K 3/06; H05K 3/284; H05K 3/303; H05K 3/3485; H05K 2201/10522; H05K 2201/10757

(57) ABSTRACT

An electronic device includes a support member, a wiring layer, a barrier metal, a bonding layer, and an electronic component. The support member includes an obverse surface facing a side in a thickness direction. The wiring layer is formed on the obverse surface. The barrier metal is formed on the wiring layer. The bonding layer is formed on the barrier metal. The electronic component is bonded to the wiring layer via the bonding layer and the barrier metal, and is electrically connected to the wiring layer. The barrier metal and the wiring layer contain mutually different metals. The barrier metal is smaller than the wiring layer as viewed in the thickness direction.

### TECHNICAL FIELD

The present disclosure relates to an electronic device and a method for manufacturing the electronic device.

### BACKGROUND ART

An electronic device provided with a plurality of electronic components has been conventionally known. JP-A-2009-147115 discloses an example of a conventional electronic device. The electronic device (a module substrate) in JP-A-2009-147115 includes a wiring board and a plurality of electronic components. The electronic components include a semiconductor element (flip-chip IC) and a passive element. The passive element may be a resistive element, an inductive element, or a capacitive element. The semiconductor element and the passive element are mounted on the wiring board. A wiring layer is disposed on a surface of the wiring board. The semiconductor element and the passive element are bonded to the wiring layer via conductive bonding members (solder layers in JP-A-2009-147115).

### BRIEF DESCRIPTION OF THE DRAWINGS

FIG. 1 is a perspective view showing an electronic device according to a first embodiment as seen from a bottom surface side.

FIG. 2 is a plan view showing the electronic device according to the first embodiment, with a sealing resin indicated by an imaginary line.

FIG. 3 corresponds to the plan view of FIG. 2, but omits the sealing resin and indicates a semiconductor element and a plurality of electronic components with imaginary lines.

FIG. 4 is a bottom view showing the semiconductor device according to the first embodiment.

FIG. 5 is a cross-sectional view taken along line V-V in FIG. 2.

FIG. 6 is a cross-sectional view taken along line VI-VI in FIG. 2.

FIG. 7 is a cross-sectional view taken along line VII-VII in FIG. 2.

FIG. 8 is a partially enlarged cross-sectional view of FIG. 7, showing a bonding portion of an electronic component in the electronic device shown in FIG. 1.

FIG. 9 is an enlarged cross-sectional view showing another example of the bonding portion of the electronic component in the electronic device shown in FIG. 1.

FIG. 10 is a bottom view showing a semiconductor element in the electronic device of FIG. 1.

FIG. 11 is an enlarged cross-sectional view taken along line XI-XI in FIG. 10.

FIG. 12 is a cross-sectional view showing a step of a method for manufacturing the electronic device according to the first embodiment.

FIG. 13 is a cross-sectional view showing a step of the method for manufacturing the electronic device according to the first embodiment.

FIG. 14 is a cross-sectional view showing a step of the method for manufacturing the electronic device according to the first embodiment.

FIG. 15 is a cross-sectional view showing a step of the method for manufacturing the electronic device according to the first embodiment.

FIG. 16 is a cross-sectional view showing a step of the method for manufacturing the electronic device according to the first embodiment.

FIG. 17 is a cross-sectional view showing a step of the method for manufacturing the electronic device according to the first embodiment.

FIG. 18 is a cross-sectional view showing a step of the method for manufacturing the electronic device according to the first embodiment.

FIG. 19 is a cross-sectional view showing a step of the method for manufacturing the electronic device according to the first embodiment.

FIG. 20 is a cross-sectional view showing a step of the method for manufacturing the electronic device according to the first embodiment.

FIG. 21 is a cross-sectional view showing a step of the method for manufacturing the electronic device according to the first embodiment.

FIG. 22 is a cross-sectional view showing a step of the method for manufacturing the electronic device according to the first embodiment.

FIG. 23 is a cross-sectional view showing a step of the method for manufacturing the electronic device according to the first embodiment.

FIG. 24 is a partially enlarged cross-sectional view showing an electronic device according to a second embodiment, and corresponds to the cross section shown in FIG. 8.

FIG. 25 is a partially enlarged cross-sectional view showing a step of a method for manufacturing the electronic device according to the second embodiment.

FIG. 26 is a partially enlarged cross-sectional view showing a step of the method for manufacturing the electronic device according to the second embodiment.

FIG. 27 is a partially enlarged cross-sectional view showing a step of the method for manufacturing the electronic device according to the second embodiment.

FIG. 28 is a partially enlarged cross-sectional view showing a step of the method for manufacturing the electronic device according to the second embodiment.

FIG. 29 is a partially enlarged cross-sectional view showing a step of the method for manufacturing the electronic device according to the second embodiment.

FIG. 30 is a partially enlarged cross-sectional view showing a step of the method for manufacturing the electronic device according to the second embodiment.

FIG. 31 is a cross-sectional view showing an electronic device according to another embodiment.

FIG. 32 is a cross-sectional view showing a step of a method for manufacturing the electronic device in FIG. 31.

FIG. 33 is a plan view showing an electronic device according to another embodiment, with a sealing resin and a semiconductor element indicated by imaginary lines.

FIG. 34 is a plan view showing an electronic device according to another embodiment, with a sealing resin and a semiconductor element indicated by imaginary lines.

### DETAILED DESCRIPTION OF EMBODIMENTS

The following describes preferred embodiments of an electronic device and a method for manufacturing the electronic device according to the present disclosure, with reference to the drawings. In the following description, the same or similar elements are denoted by the same reference numerals and redundant descriptions of such elements are omitted.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a part of an object B”. The phrase “an object A (or the material thereof) contains a material C” includes “an object A (or the material thereof) is made of a material C” and “an object A (or the material thereof) is mainly composed of a material C”. Further, the phrase “a plane A faces (a first side or a second side) in a direction B” is not limited to the case where the angle of the plane A with respect to the direction B is 90°, but also includes the case where the plane A is inclined to the direction B. The phrase “a plane A is perpendicular to a plane B” is not limited to the case where the angle of the plane A with respect to the plane B is exactly 90°, but also includes the case where the plane A is substantially perpendicular to the plane B.

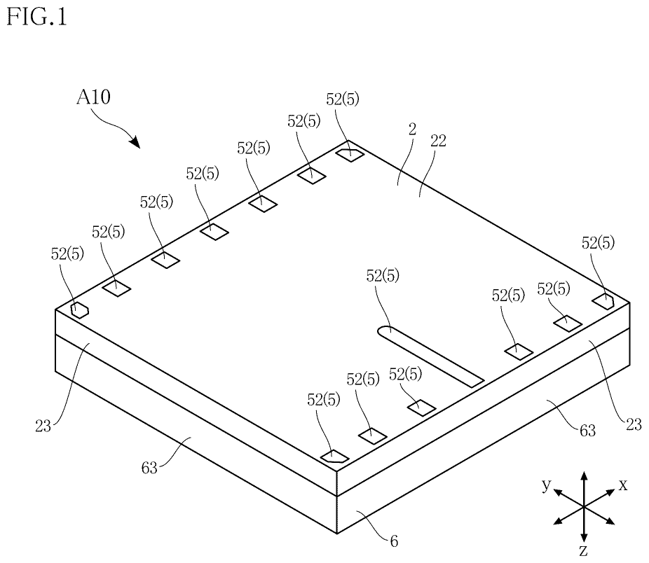

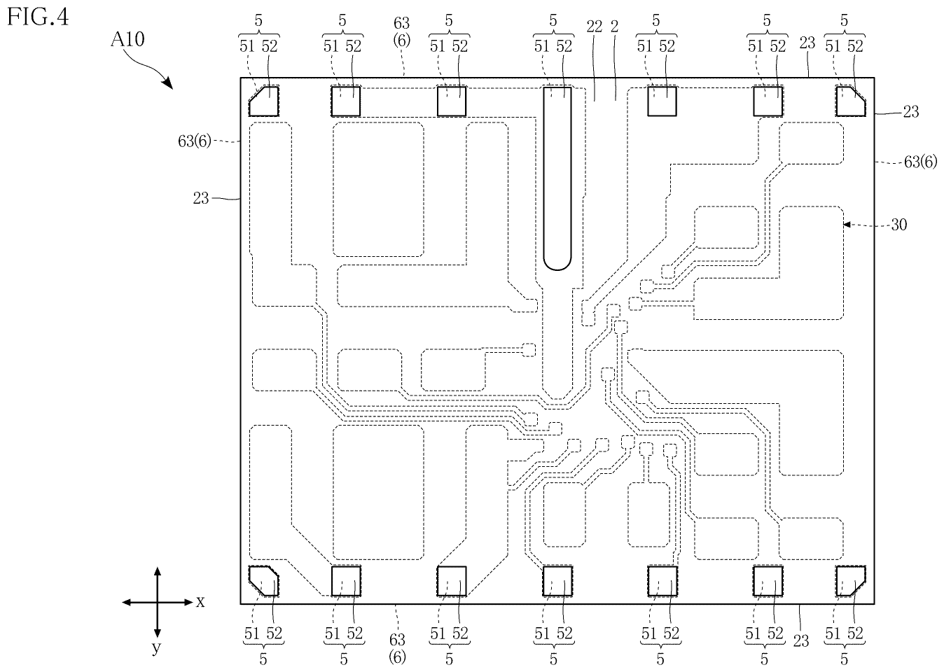

FIGS. 1 to 11 show an electronic device A10 according to a first embodiment. The electronic device A10 includes a semiconductor element 1, a plurality of electronic components 19, a support member 2, a wiring layer 30, a plurality of barrier metals 35, a plurality of bonding layers 41, a plurality of bonding layers 42, a plurality of terminals 5, and a sealing resin 6.

For convenience of explanation, reference will be made to a thickness direction z, a first direction x, and a second direction y that are perpendicular to each other. For example, the thickness direction z corresponds to the thickness direction of the electronic device A10. In the following description, the terms such as “top”, “bottom”, “upward”, “downward”, “upper surface”, and “lower surface” are used to indicate the relative positions of components and the like in the thickness direction z, and do not necessarily define the relationship with respect to the direction of gravity. In addition, “plan view” refers to the view seen in the thickness direction z.

The electronic device A10 is surface-mountable onto the wiring board of an electronic apparatus or an electric vehicle, for example. The electronic device A10 is of a leadless package type, specifically a quad flat non-leaded (QFN) package type. The electronic device A10 has a rectangular shape in plan view.

The semiconductor element 1 is a component that forms the functional core of the electronic device A10. The semiconductor element 1 is an integrated circuit such as an LSI. Unlike this example, the semiconductor element 1 may be a voltage control element such as a low drop out regulator (LDO), an amplification element such as an operational amplifier, or a discrete element such as a transistor or a diode. The semiconductor element 1 has a rectangular shape in plan view. The semiconductor element 1 is supported by the support member 2. The semiconductor element 1 overlaps with the support member 2 in plan view.

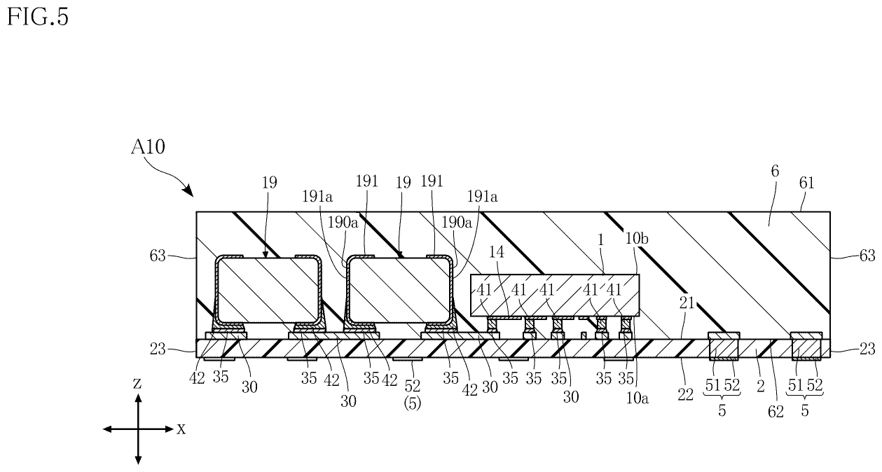

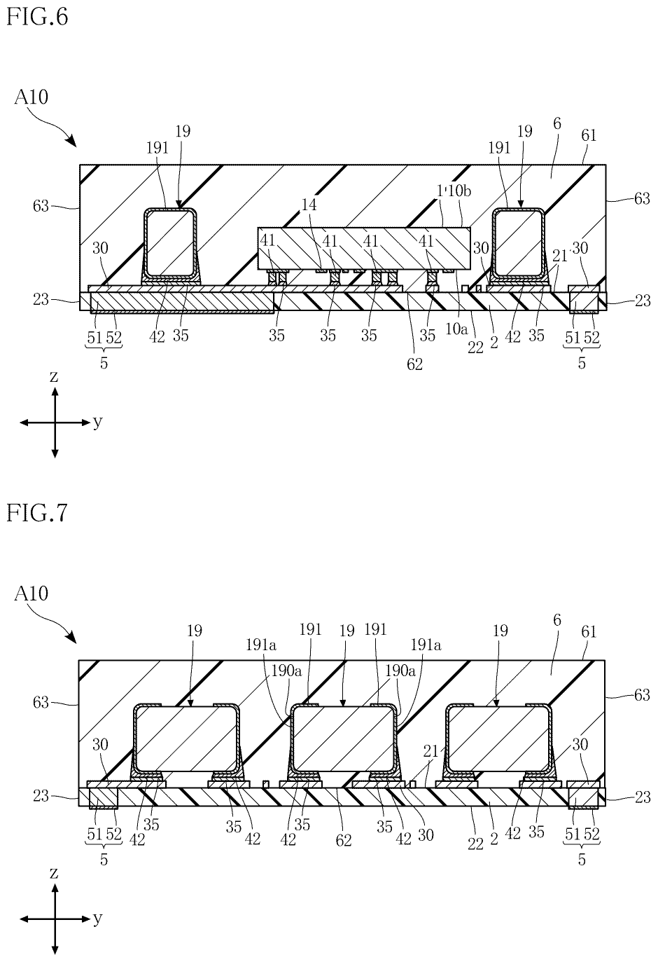

As shown in FIGS. 5 and 6, the semiconductor element 1 has an element obverse surface 10a and an element reverse surface 10b. The element obverse surface 10a and the element reverse surface 10b are spaced apart from each other in the thickness direction z. The element obverse surface 10a and the element reverse surface 10b are opposite to each other. The element obverse surface 10a faces the support member 2.

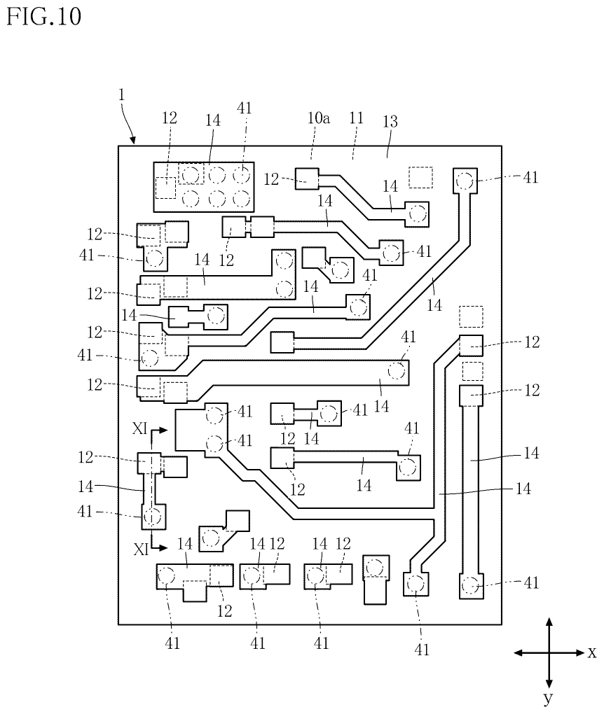

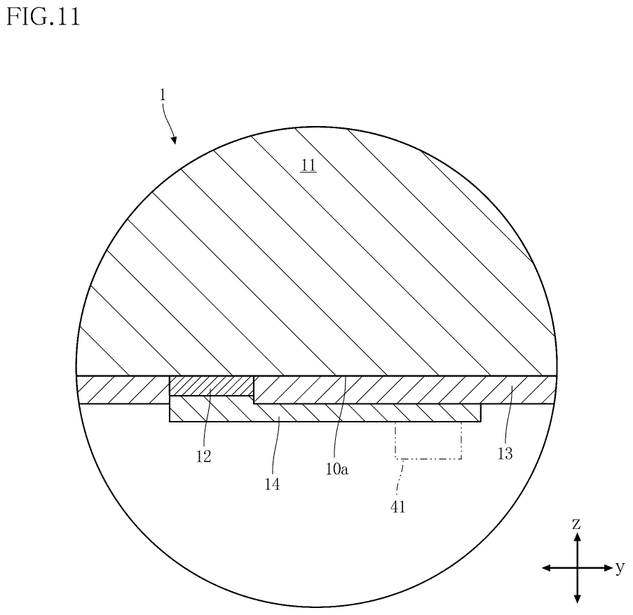

As shown in FIGS. 10 and 11, the semiconductor element 1 includes a body 11, a plurality of pads 12, an insulating film 13, and a plurality of redistribution wirings 14. The pads 12 are electrically connected to a circuit (not illustrated) configured in the body 11. The element obverse surface 10a corresponds to the lower surface (the surface facing downward in the thickness direction z) of the body 11. The insulating film 13 is disposed on the lower surface (the element obverse surface 10a) of the body 11. The pads 12 are exposed from the insulating film 13. The insulating film 13 contains polyimide or polybenzoxazole. The redistribution wirings 14 are provided on the insulating film 13. Each of the redistribution wirings 14 is connected to at least one of the pads 12. The redistribution wirings 14 contain copper (Cu). As shown in FIGS. 10 and 11, each of the redistribution wirings 14 is bonded to the wiring layer 30 via at least one of the bonding layers 41. As a result, each of the pads 12 is electrically connected to the wiring layer 30 via a redistribution wiring 14 and a bonding layer 41.

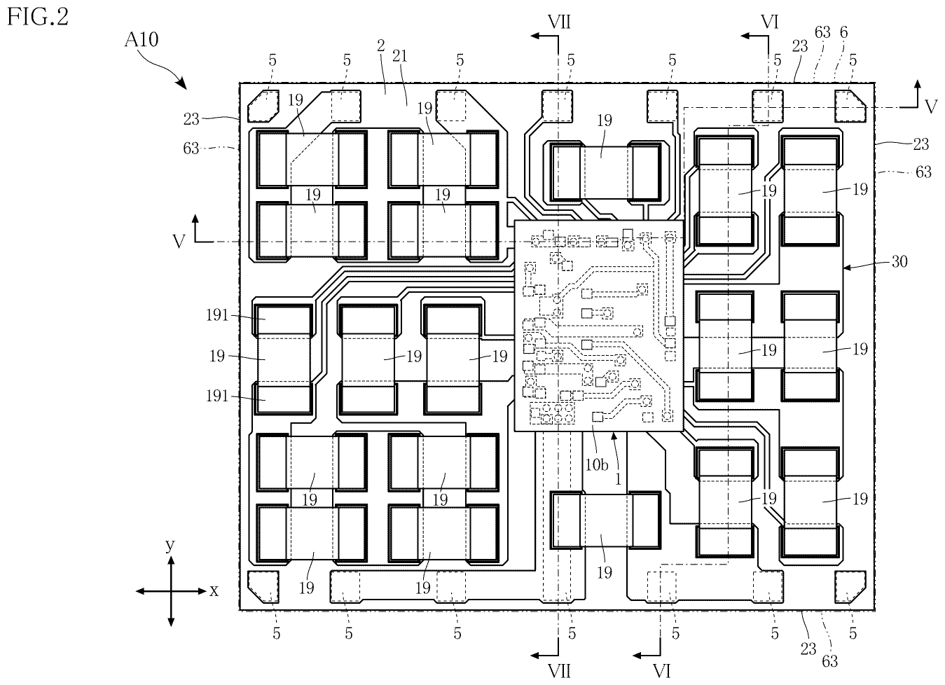

As shown in FIGS. 2 and FIGS. 5 to 7, the electronic components 19 are supported by the support member 2. The electronic components 19 are surface mount devices (SMD). Each of the electronic components 19 may be one of a resistor, a capacitor, or a diode. The electronic components 19, as well as the semiconductor element 1, are the functional elements of the electronic device A10. As shown in FIGS. 5 and 7, each of the electronic components 19 has a pair of side surfaces 190a. The pair of side surfaces 190a face in a direction perpendicular to the thickness direction z (perpendicular direction). The pair of side surfaces 190a face away from each other in the perpendicular direction. In the illustrated example, the electronic components 19 include those with the perpendicular direction being the first direction x and those with the perpendicular direction being the second direction y. As shown in FIGS. 5 and 7, each of the electronic components 19 includes a pair of terminals 191. The pair of terminals 191 of each electronic component 19 are arranged at the respective sides in the perpendicular direction. Each of the pair of terminals 191 includes a side electrode 191a. The side electrode 191a of each terminal 191 covers a corresponding side surface 190a. The number of electronic components 19 is not limited to the illustrated example.

As shown in FIG. 2 and FIGS. 5 to 7, the support member 2 supports the semiconductor element 1 and the electronic components 19. The support member 2 contains a resin material, for example. The resin material is the same as the sealing resin 6, but may be different from the scaling resin 6 in another example. The resin material of the support member 2 may be mixed with a filler such as silica. Alternatively, the support member 2 may contain a single-crystal intrinsic semiconductor (e.g., silicon (Si)) instead of a resin material. As shown in FIGS. 2 to 4, the support member 2 may have a rectangular shape in plan view. The thickness (the dimension in the thickness direction z) of the support member 2 is not particularly limited, but may be at least 30 μm and at most 200 μm. The support member 2 has an obverse surface 21, a reverse surface 22, and a plurality of side surfaces 23.

As shown in FIGS. 5 to 7, the obverse surface 21 and the reverse surface 22 are spaced apart from each other in the thickness direction z. The obverse surface 21 and the reverse surface 22 are opposite to each other. The obverse surface 21 is the upper surface of the support member 2, and the reverse surface 22 is the lower surface of the support member 2. The obverse surface 21 faces the semiconductor element 1 (the element obverse surface 10a). The reverse surface 22 faces a wiring board when the electronic device A10 is mounted on the wiring board. In the present embodiment, the obverse surface 21 is covered with the sealing resin 6, and the reverse surface 22 is exposed from the sealing resin 6.

As shown in FIGS. 2 to 10, the side surfaces 23 are located between the obverse surface 21 and the reverse surface 22. The upper end of each side surface 23 in the thickness direction z is connected to the obverse surface 21, and the lower end of each side surface 23 in the thickness direction z is connected to the reverse surface 22. Each of the side surfaces 23 is flat and perpendicular to the obverse surface 21 and the reverse surface 22.

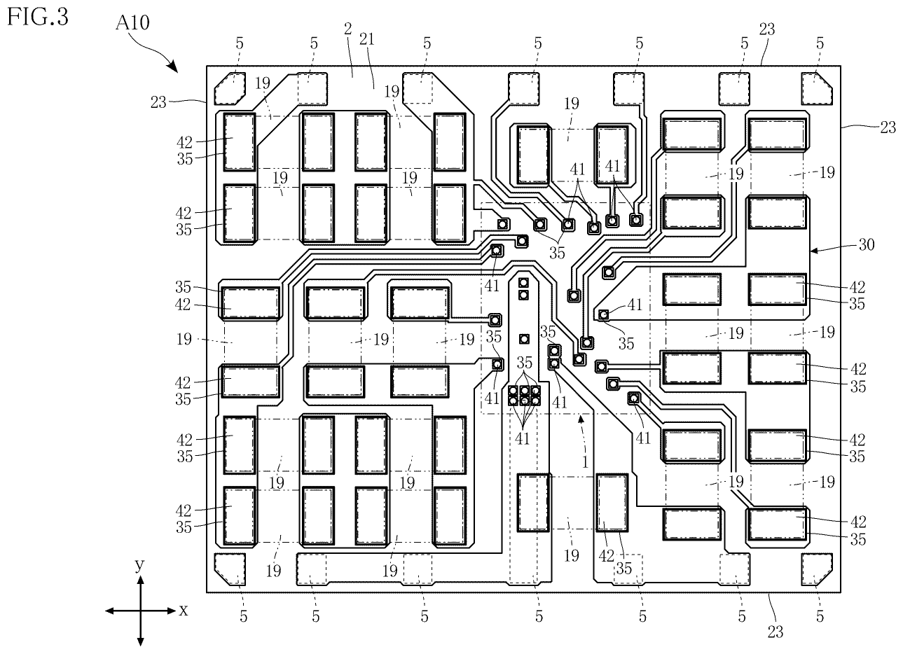

The wiring layer 30 is a conductor disposed in the electronic device A10. The wiring layer 30 contains Cu, for example. The wiring layer 30 may be a laminate including a seed layer (that contains titanium (Ti), for example) and a metal layer (that contains Cu, for example), or may be a single layer made of a conductor. As shown in FIG. 3, the wiring layer 30 includes a plurality of pattern wiring portions that are separated from each other. The pattern wiring portions include one electrically connected to the semiconductor element 1, one electrically connected to one of the electronic components 19, and one not electrically connected to either the semiconductor element 1 or any of the electronic components 19. In the present embodiment, the wiring layer 30 is formed on the obverse surface 21, and is in contact with the obverse surface 21. The thickness (the dimension in the thickness direction z) of the wiring layer 30 is at least 3 μm and at most 100 μm.

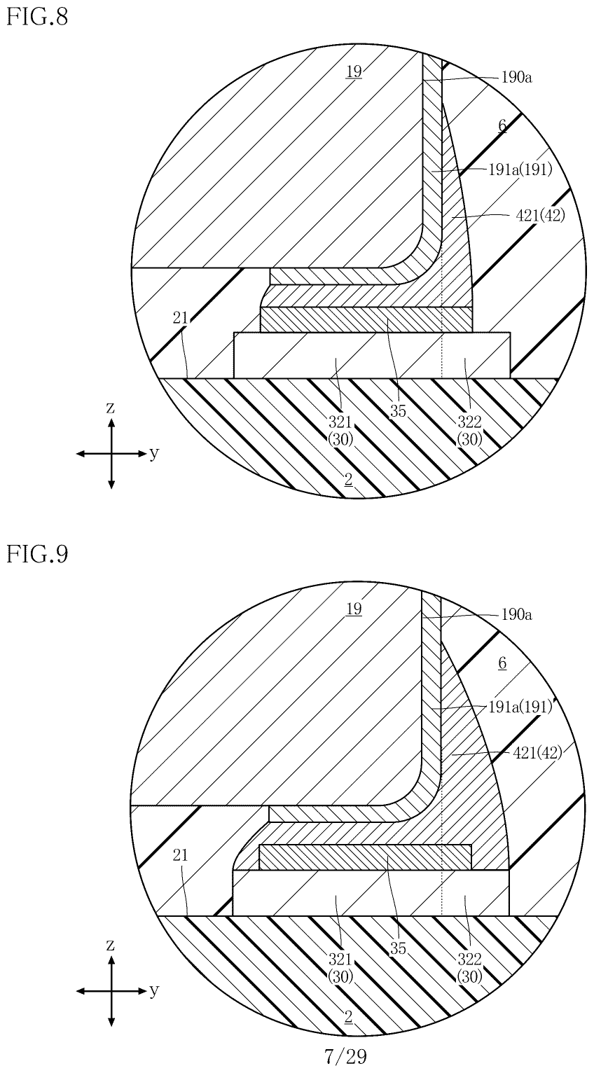

As shown in FIG. 8 or 9, the wiring layer 30 includes an intervening portion 321 and an extending portion 322. The intervening portion 321 is a part of the wiring layer 30 that is interposed between the support member 2 and the electronic component 19 in the thickness direction z. The extending portion 322 is connected to the intervening portion 321. The extending portion 322 is a part of the wiring layer 30 that is located outside the electronic component 19 in plan view.

The barrier metals 35 are formed on the wiring layer 30. Each of the barrier metals 35 contains a metal different from the wiring layer 30. The metal contained in each barrier metal 35 is nickel (Ni). Each of the barrier metals 35 is smaller than the wiring layer 30 in plan view. Thus, as shown in FIG. 8 or 9, a step is formed between each barrier metal 35 and the wiring layer 30. In the present embodiment, the wiring layer 30 protrudes outward from each barrier metal 35 in plan view. As shown in FIGS. 5 and 6, the barrier metals 35 include those interposed between the bonding layers 41 and the wiring layer 30 and those interposed between the bonding layers 42 and the wiring layer 30. Note that the barrier metals 35 may not include those interposed between the bonding layers 41 and the wiring layer 30. For example, the thickness of each barrier metal 35 is at least 1 μm and at most 10 μm.

Each of the bonding layers 41 bonds the wiring layer 30 and one of the redistribution wirings 14 of the semiconductor element 1. The semiconductor element 1 is electrically connected to the wiring layer 30 via the bonding layers 41. Each of the bonding layers 41 is a conductive bonding material. The bonding layers 41 are made of solder, for example. The solder contains an alloy containing tin (Sn) (e.g., Sn-silver (Ag) alloy), and also contains flux. Note that the composition of each bonding layer 41 is not limited to this example. The thickness (the dimension in the thickness direction z) of each bonding layer 41 is not particularly limited, but may be at least 15 μm and at most 100 μm.

Each of the bonding layers 42 bonds the wiring layer 30 and one of the terminals 191 of an electronic component 19. Each of the bonding layers 42 is formed on a corresponding barrier metal 35. Each of the bonding layers 42 may not be in contact with the wiring layer 30 as shown in FIG. 8, may be in contact with the wiring layer 30 as shown in FIG. 9, or may include a portion in contact with the wiring layer 30 and a portion not in contact with the wiring layer 30. In the example shown in FIG. 8, the entirety of each bonding layer 42 is arranged on a corresponding barrier metal 35. In the example shown in FIG. 9, each of the bonding layers 42 covers the entirety of a corresponding barrier metal 35. Each of the bonding layers 42 is made of a conductive bonding material. Each of the bonding layers 42 includes an alloy layer formed on a corresponding barrier metal 35. The alloy layer contains Sn. For example, the alloy layer is an Sn—Ag alloy. Note that the composition of each bonding layer 42 is not limited to this example. The bonding layers 42 may be made of solder, for example. Each of the bonding layers 42 may or may not contain flux. The thickness (the dimension in the thickness direction z) of each bonding layer 42 is not particularly limited, but may be at least 1 μm and at most 20 μm.

As shown in FIG. 8 or 9, each of the bonding layers 42 includes a fillet portion 421. The fillet portion 421 is in contact with a corresponding side electrode 191a. In the example shown in FIG. 8 or 9, the side surface of the fillet portion 421 is curved outward, but may be curved inward or may not be curved at all.

Each of the terminals 5 is a conductor electrically connected to the wiring layer 30 and exposed to the outside from the electronic device A10. Each of the terminals 5 is a terminal used when the electronic device A10 is mounted onto a wiring board. As shown in FIGS. 5 to 7, each of the terminals 5 penetrates through the support member 2 in the thickness direction z. The terminals 5 include one electrically connected to the semiconductor element 1 via the wiring layer 30, one electrically connected to the semiconductor element 1 and one of the electronic components 19 via the wiring layer 30, one electrically connected to the one of the electronic components 19 via the wiring layer 30, and one not electrically connected to either the semiconductor element 1 or any of the electronic components 19. In the illustrated example, each of the terminals 5 is disposed outside the semiconductor element 1 in plan view, and does not overlap with either the semiconductor element 1 or any of the electronic components 19 in plan view. Unlike this example, some of the terminals 5 may each overlap with either the semiconductor element 1 or one of the electronic components 19 in plan view.

As shown in FIGS. 5 to 7, each of the terminals 5 includes a columnar portion 51 and an external electrode portion 52. Unless otherwise specified, the description of the columnar portion 51 and the external electrode portion 52 given below commonly applies to each of the terminals 5.

As shown in FIGS. 5 to 7, the columnar portion 51 penetrates through the support member 2 in the thickness direction z. The columnar portion 51 contains a metal material, for example. The metal material is not particularly limited, but may be Cu. The shape of the columnar portion 51 in plan view is not particularly limited, but may be a rectangle or a polygon in the illustrated example. The upper surface (the surface facing upward in the thickness direction z) of the columnar portion 51 is flush with the obverse surface 21 of the support member 2. The upper surface of the columnar portion 51 is in contact with the wiring layer 30. Note that the terminals 5 may include one having a columnar portion 51 whose upper surface is not in contact with the wiring layer 30. Such a terminal 5 serves as a dummy terminal. The lower surface (the surface facing downward in the thickness direction z) of the columnar portion 51 is exposed from the support member 2. The lower surface of the columnar portion 51 is flush with the reverse surface 22 of the support member 2, for example. In the present embodiment, the columnar portion 51 of every terminal 5 has side surfaces (each facing in the first direction x or in the second direction y) covered with the support member 2. Unlike this example, the columnar portions 51 of some of the terminals 5 may have side surfaces exposed to the outside.

As shown in FIGS. 5 to 7, the external electrode portion 52 is in contact with a part of the columnar portion 51 that is exposed from the reverse surface 22 of the support member 2. The external electrode portion 52 protrudes from the reverse surface 22. The external electrode portion 52 is formed by electroless plating. In one example, the external electrode portion 52 is made up of a plurality of metal layers stacked in the order of an Ni layer, a palladium (Pd) layer, and a gold (Au) layer, starting from the side in contact with the columnar portion 51. In another example, the external electrode portion 52 may be made up of a plurality of metal layers stacked in the order of an Ni layer and an Au layer or a plurality of metal layers stacked in the order of a Cu layer, an Ag layer, and an Sn layer, starting from the side in contact with the columnar portion 51. The material and formation method of the external electrode portion 52 are not limited to these examples.

The sealing resin 6 is made of a synthetic resin mainly containing black epoxy resin, for example. The epoxy resin in the sealing resin 6 may be mixed with a filler such as silica. As shown in FIG. 2 and FIGS. 4 to 7, the sealing resin 6 covers elements such as the semiconductor element 1, the electronic components 19, and the wiring layer 30. As shown in FIG. 2 and FIGS. 5 to 7, the sealing resin 6 also covers a part of the support member 2, the bonding layers 41, and the bonding layers 42. The sealing resin 6 is formed on the obverse surface 21. The sealing resin 6 has a rectangular shape in plan view. As shown in FIGS. 1 to 7, the sealing resin 6 has a resin obverse surface 61, a resin reverse surface 62, and a plurality of resin side surfaces 63.

As shown in FIGS. 5 to 7, the resin obverse surface 61 and the resin reverse surface 62 are spaced apart from each other in the thickness direction z. The resin obverse surface 61 and the resin reverse surface 62 face away from each other in the thickness direction z. The resin obverse surface 61 faces the same side as the obverse surface 21 in the thickness direction z, and the resin reverse surface 62 faces the same side as the reverse surface 22 in the thickness direction z. The resin reverse surface 62 is in contact with the obverse surface 21. The resin reverse surface 62 has recesses and protrusions corresponding to the shape of the wiring layer 30. As shown in FIGS. 5 to 7, the resin side surfaces 63 are located between the resin obverse surface 61 and the resin reverse surface 62 in the thickness direction z, and are connected to these surfaces. The resin side surfaces 63 are flush with the respective side surfaces 23.

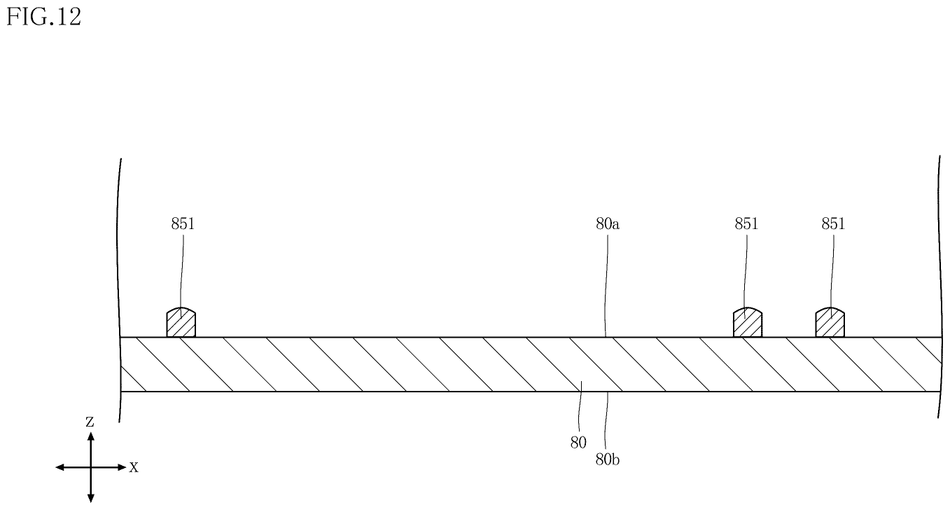

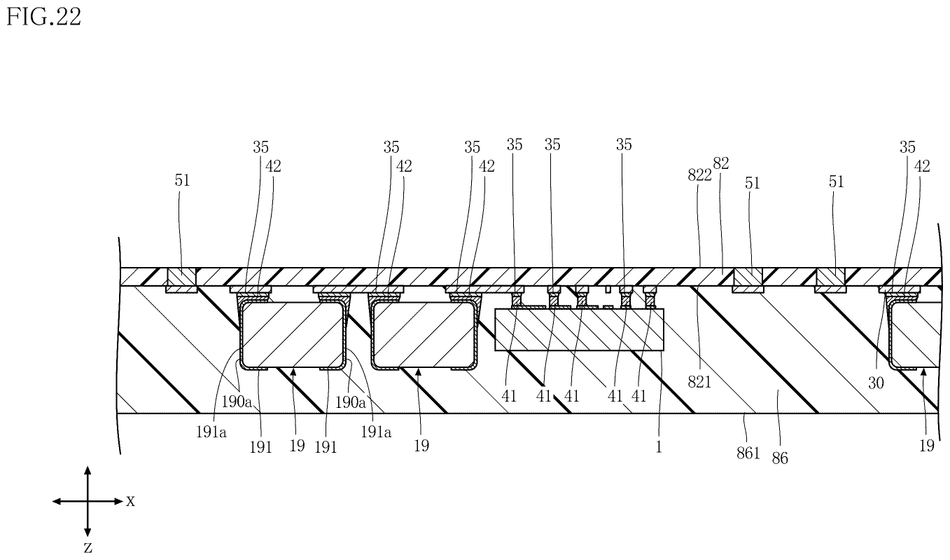

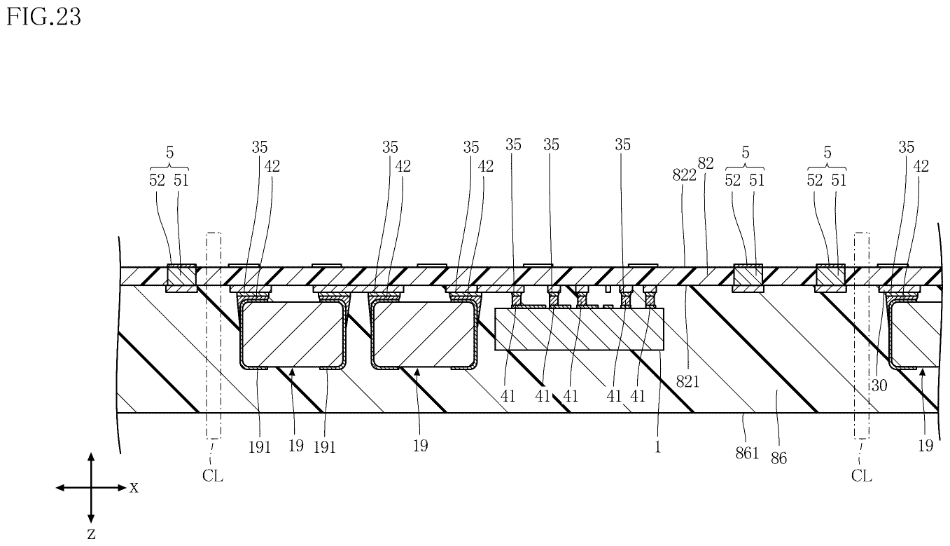

The following describes an example of a method for manufacturing the electronic device A10, with reference to FIGS. 12 to 23. FIGS. 12 to 23 are cross-sectional views each showing a step of the method for manufacturing the electronic device A10. These cross-sectional views are taken along the same line as in FIG. 7. The cross-sectional views in FIGS. 22 and 23 are reversed in the thickness direction z as compared to the cross-sectional views of FIGS. 12 to 21.

First, as shown in FIG. 12, a support substrate 80 is prepared, and a plurality of columnar conductors 851 are formed on the support substrate 80. The support substrate 80 contains a single-crystal intrinsic semiconductor material, for example. The semiconductor material is Si, for example. In the step of preparing the support substrate 80, a silicon wafer, which serves as the support substrate 80, may be prepared. The support substrate 80 has a substrate obverse surface 80a and a substrate reverse surface 80b that face away from each other in the thickness direction z. The columnar conductors 851 may be formed through the following steps. First, a seed layer is formed on the substrate obverse surface 80a. The seed layer may be formed by sputtering. Next, a resist is patterned on the seed layer to form the columnar conductors 851 by electroplating. Then, the resist and unnecessary parts of the seed layer are removed. Through the steps described above, the columnar conductors 851 are formed on the substrate obverse surface 80a of the support substrate 80. The columnar conductors 851 will be formed into the columnar portions 51 of the terminals 5 in a subsequent step.

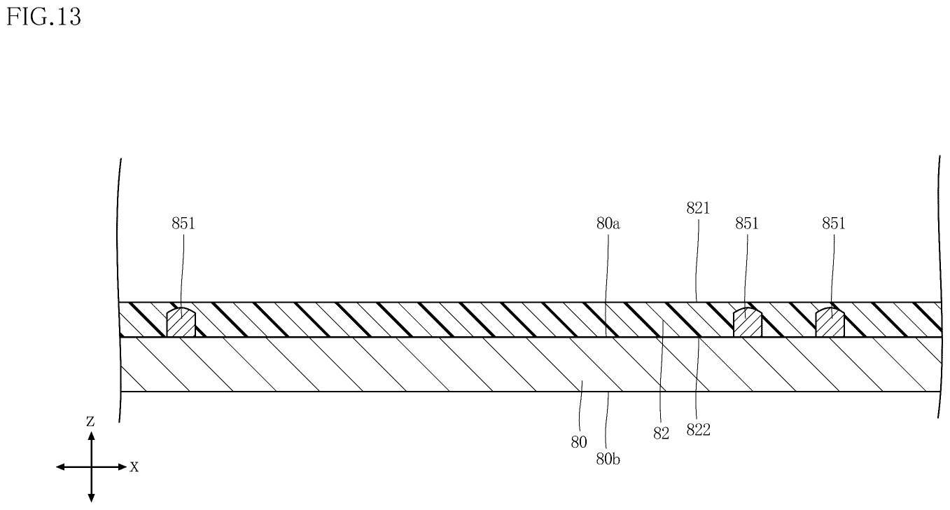

Next, as shown in FIG. 13, a first resin layer 82 is formed on the substrate obverse surface 80a of the support substrate 80 to cover the columnar conductors 851. The first resin layer 82 is formed by molding, for example. The first resin layer 82 is made of a synthetic resin mainly containing black epoxy resin, for example. The first resin layer 82 may be made of another insulating resin material instead of the synthetic resin. The first resin layer 82 has an obverse surface 821 and a bottom surface 822 facing away from each other in the thickness direction z. The obverse surface 821 faces in the same direction as the substrate obverse surface 80a, and the bottom surface 822 faces the substrate obverse surface 80a. The first resin layer 82 will be formed into the support member 2 in a subsequent step.

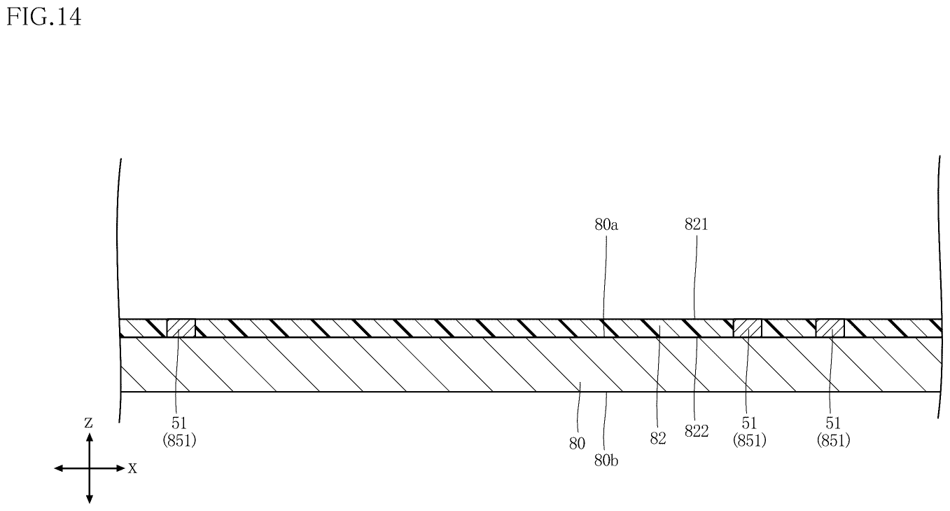

Next, as shown in FIG. 14, the first resin layer 82 is ground. The grinding of the first resin layer 82 is performed from the obverse surface 821 side until the columnar conductors 851 are exposed from the obverse surface 821. A method for the grinding is not particularly limited. In addition, a method other than grinding can be selected to reduce the height of the first resin layer 82. As a result, the columnar portions 51 are formed from the columnar conductors 851. The first resin layer 82 formed through the above steps is an example of a “support member”. Thus, in the present embodiment, the steps of preparing the support substrate 80 to grinding the first resin layer 82 constitute an example of “a step of preparing a support member”.

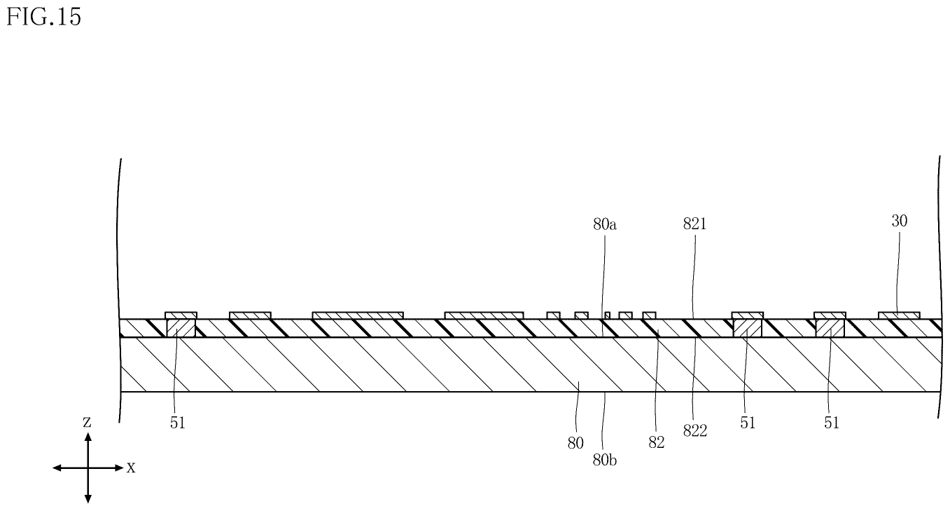

Next, as shown in FIG. 15, the wiring layer 30 is formed. The wiring layer 30 is formed through the following steps. First, a seed layer is formed on the obverse surface 821 and the columnar portions 51. The seed layer may be formed by sputtering. For example, a Ti layer and a Cu layer are stacked in sequence to form a seed layer. Then, a resist is patterned on the seed layer, and a metal layer is formed by electroplating. For example, the metal layer contains Cu. Subsequently, the resist and unnecessary parts of the seed layer (i.e., parts exposed from the metal layer) are removed. Through these steps, the wiring layer 30 is formed.

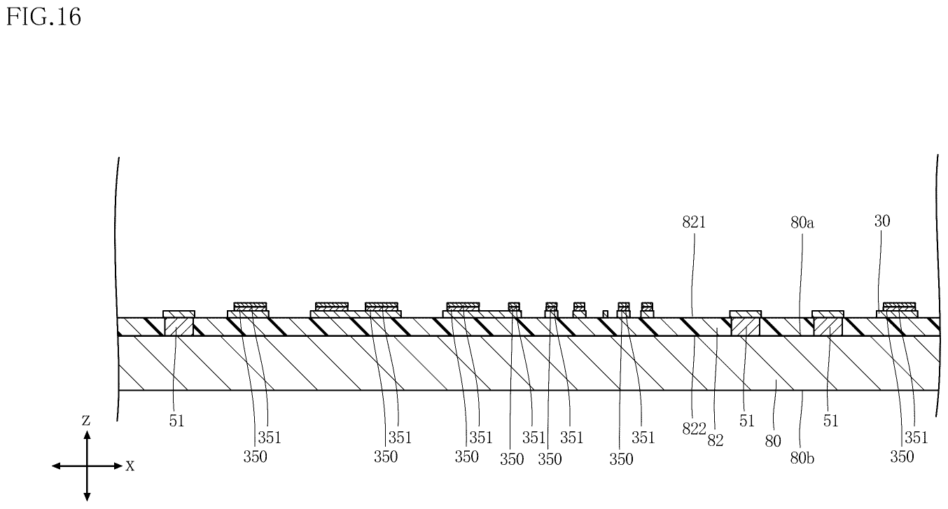

Next, as shown in FIG. 16, a plurality of barrier layers 350 and a plurality of plating layers 351 are formed in sequence. Each of the barrier layers 350 contains a metal different from the wiring layer 30, and may contain Ni as one example. Each of the plating layers 351 contains Sn and Ag(Sn—Ag alloy). The method for forming the barrier layers 350 and the plating layers 351 is not particularly limited, but may be electroplating. In the electroplating, a seed layer that serves as a conductive path may be newly formed, or the seed layer formed during the step of forming the wiring layer 30 may be used without being removed. In the present embodiment, the barrier layers 350 and the plating layers 351 are formed in the area where the semiconductor element 1 is to be bonded and in the area where the electronic components 19 are to be bonded. Each of the barrier layers 350 formed is smaller than the wiring layer 30 in plan view.

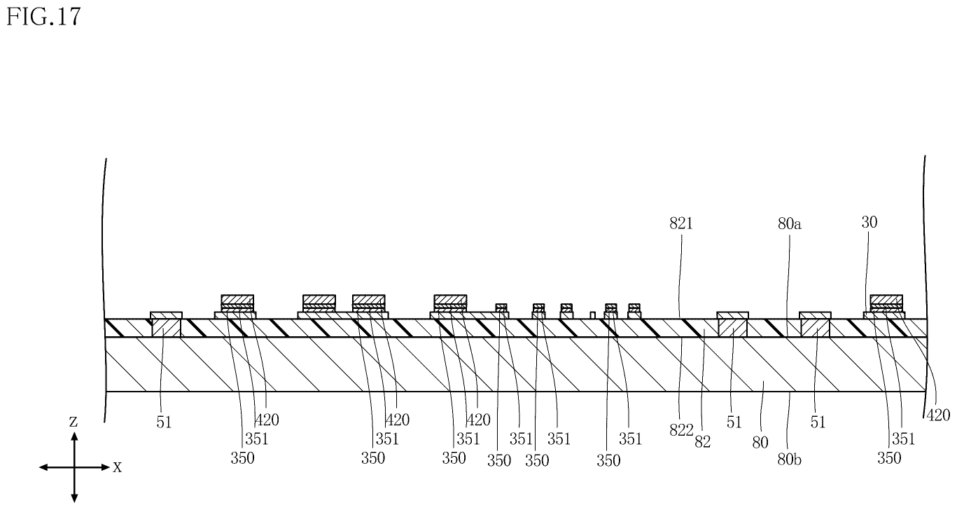

Next, as shown in FIG. 17, a plurality of bonding layers 420 are formed. In the step of forming the bonding layers 420, solder paste serving as each of the bonding layers 420 is formed on corresponding plating layers 351 by screen printing. The corresponding plating layers 351 refer to plating layers 351, out of the plurality of plating layers 351, to which the electronic components 19 are to be bonded.

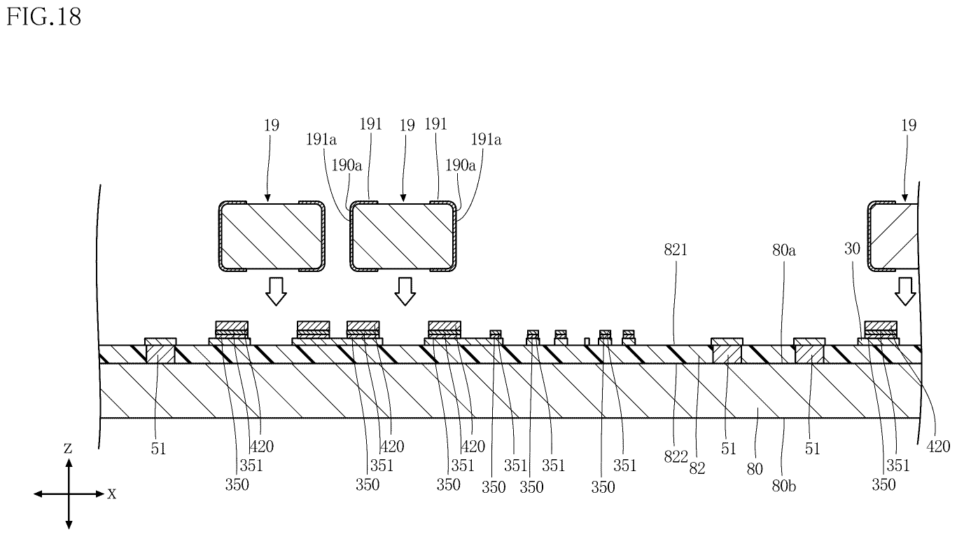

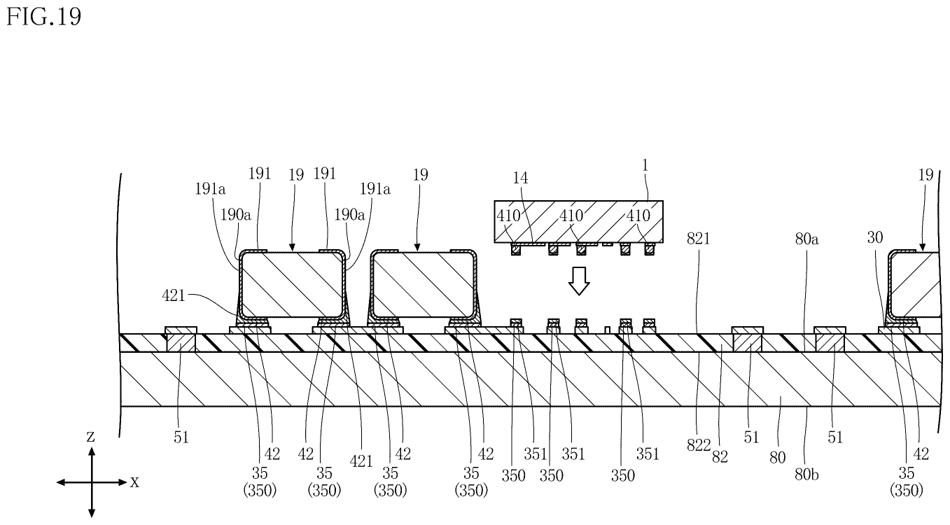

Next, as shown in FIGS. 18 and 19, the electronic components 19 are mounted and then bonded. As shown in FIG. 18, in the step of mounting the electronic components 19, the terminals 191 of the electronic components 19 are placed in correspondence with the bonding layers 420. Next, reflow is performed in the state where the electronic components 19 are placed. Heat from the reflow causes the bonding layers 420 to melt. At this point, the plating layers 351 also melt due to the heat from the reflow, and the plating layers 351 and the bonding layers 420 are mixed together as a result. Next, the melted bonding layers 420 and the plating layers 351 are cooled. As a result, the bonding layers 420 and the plating layers 351 are solidified, and the electronic components 19 are bonded. At this point, the bonding layers 420 and the plating layers 351 are fused together to become the bonding layers 42. Thus, as shown in FIG. 19, the bonding layers 42 come into contact with the corresponding barrier layers 350, and these barrier layers 350 become barrier metals 35. As shown in FIG. 19, a fillet portion 421 is formed in each of the bonding layers 42.

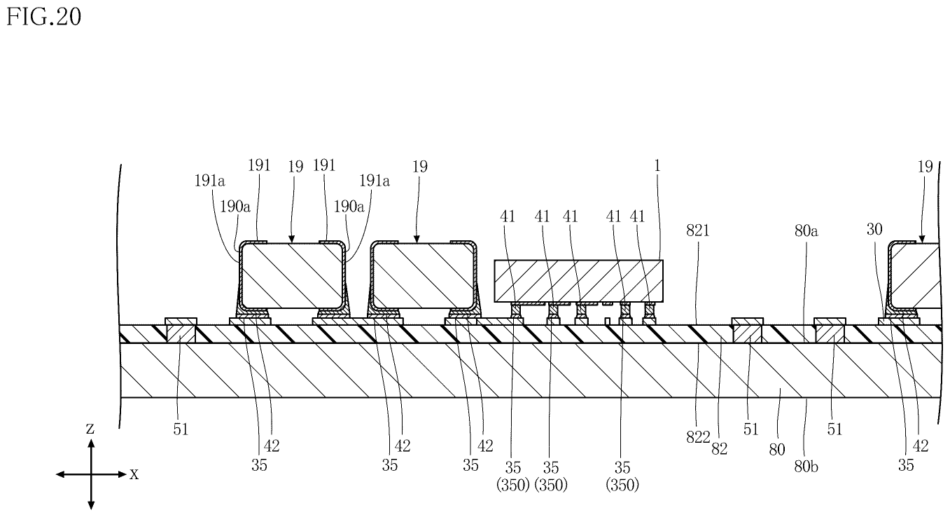

Next, as shown in FIGS. 19 and 20, the semiconductor element 1 is mounted and then bonded. As shown in FIG. 19, in the step of mounting the semiconductor element 1, bonding layers 410 formed on the semiconductor element 1 are placed in correspondence with plating layers 351. In the present embodiment, the bonding layers 410 are formed on the redistribution wirings 14 of the semiconductor element 1. However, the bonding layers 410 may be formed on corresponding plating layers 351 instead. The corresponding plating layers 351 refer to plating layers 351, out of the plurality of plating layers 351, to which the semiconductor element 1 is to be bonded. Each of the bonding layers 410 formed on the semiconductor element 1 contains flux. Next, reflow is performed in the state where the semiconductor element 1 is placed. Heat from the reflow causes the bonding layers 410 to melt. At this point, the plating layers 351 also melt due to the heat from the reflow, and the plating layers 351 and the bonding layers 410 are mixed together as a result. Next, the melted bonding layers 410 and the plating layers 351 are cooled. As a result, the bonding layers 410 and the plating layers 351 are solidified, and the semiconductor element 1 is bonded. At this point, the bonding layers 410 and the plating layers 351 are fused together to become the bonding layers 41. Thus, as shown in FIG. 20, the bonding layers 41 come into contact with the corresponding barrier layers 350, and these barrier layers 350 become barrier metals 35.

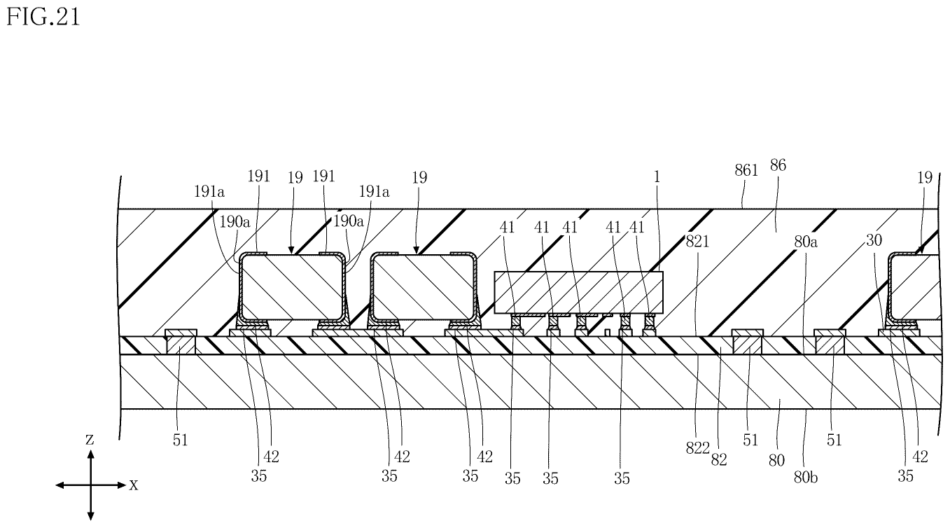

Next, as shown in FIG. 21, a second resin layer 86 is formed. The second resin layer 86 is formed over the first resin layer 82 to cover the semiconductor element 1, the electronic components 19, and the wiring layer 30. The second resin layer 86 is formed by molding, for example. The second resin layer 86 is made of a synthetic resin mainly containing black epoxy resin, for example. The second resin layer 86 may be made of another insulating resin material instead of the synthetic resin. The second resin layer 86 will be formed into the sealing resin 6 in a subsequent step. The second resin layer 86 has a top surface 861 facing a side in the thickness direction z. The top surface 861 corresponds to the resin obverse surface 61 of the sealing resin 6.

Next, as shown in FIG. 22, the support substrate 80 is removed. In the step of removing the support substrate 80, the support substrate 80 may be ground from the substrate reverse surface 80b side, in the state shown in FIG. 21. In this grinding step, the support substrate 80 is ground from the substrate reverse surface 80b side. In the illustrated example, the grinding is performed continuously even after the support substrate 80 is removed so as to reduce the height of each of the first resin layer 82 and the columnar portions 51. This height reduction may be omitted. Next, as shown in FIG. 23, the external electrode portions 52 are formed. The external electrode portions 52 are formed on the top surfaces of the columnar portions 51 that are exposed from the reverse surface 22. The external electrode portions 52 are formed by electroless plating. In the electroless plating, an Ni layer, a Pd layer, and an Au layer are stacked in this order to form each external electrode portion 52 from the side in contact with a corresponding columnar portion 51. As a result, the terminals 5, each including a columnar portion 51 and an external electrode portion 52, are formed.

Subsequently, the second resin layer 86 is cut along cut lines CL shown in FIG. 23 and divided into individual pieces. The cutting of the second resin layer 86 may be performed by a dicing process with a dicing blade. The sealing resin 6 of the electronic device A10 is formed by dividing the second resin layer 86 at the cut lines CL.

The electronic device A10 shown in FIGS. 1 to 11 is manufactured through the steps as described above. The manufacturing method of the electronic device A10 is not limited to the above example. For example, the electronic device A10 is manufactured as follows when the support member 2 contains a single-crystal intrinsic semiconductor (e.g., Si). First, grooves are formed in the support substrate 80 (silicon wafer) by etching or the like. Next, the columnar conductors 851 are formed in the grooves. Then, the wiring layer 30 is formed without forming the first resin layer 82. After the second resin layer 86 is formed, the support substrate 80 is not removed but rather ground until the columnar conductors 851 in the grooves are exposed. In this configuration, the support substrate 80 is an example of the “support member”. By changing to the steps as described above, the electronic device A10 manufactured will include a support member 2 made of a semiconductor material.

The functions and advantages of the electronic device A10 and the manufacturing method of the electronic device A10 are as follows.

The electronic device A10 includes the barrier metals 35, the bonding layers 42, and the electronic components 19. The barrier metals 35 are formed on the wiring layer 30, and the bonding layers 42 are formed on the barrier metals 35. The electronic components 19 are bonded to the wiring layer 30 via the bonding layers 42 and the barrier metals 35. Each of the barrier metals 35 is smaller than the wiring layer 30 as viewed in the thickness direction z. In this configuration, steps are formed between the wiring layer 30 and the barrier metals 35. The steps can suppress the wetting and spreading of the bonding layers 42 along the wiring layer 30. Defects of the bonding layers 42 that reduce the reliability of the electronic device A10 include insufficient thickness (small dimension in the thickness direction z) of each bonding layer 42. If the thickness of each bonding layer 42 in the electronic device A10 is insufficient, the bonding strength of each electronic component 19 will decrease. As described above, if the bonding layers 42 get wet and spread along the wiring layer 30, the thickness of each of the bonding layers 42 may become insufficient. However, as described above, the electronic device A10 can suppress the wetting and spreading of the bonding layers 42 along the wiring layer 30, which makes it possible to avoid insufficient thickness of each bonding layer 42. In other words, the electronic device A10 can suppress a decrease in the bonding strength of the electronic components 19, and thus can suppress a decrease in reliability.

In the electronic device A10, the barrier metals 35 are provided between the wiring layer 30 and the bonding layers 42. This configuration can reduce the area of each bonding layer 42 in contact with the wiring layer 30. For example, when the bonding layers 42 are solder and the wiring layer 30 contains Cu, the wiring layer 30 may penetrate into the bonding layers 42 in the area where the bonding layers 42 are directly in contact with the wiring layer 30. This penetration may cause poor electrical conductivity in the wiring layer 30. However, in the electronic device A10, the barrier metals 35 can reduce the contact area between each bonding layer 42 and the wiring layer 30, and thus can suppress poor electrical conductivity in the wiring layer 30. In other words, the electronic device A10 can suppress a decrease in reliability.

The manufacturing method of the electronic device A10 includes: a step of forming the barrier layers 350 on the wiring layer 30 (barrier layer formation step); a step of forming the plating layers 351 on the barrier layers 350 (plating layer formation step); a step of forming the bonding layers 420 on the plating layers 351 (bonding layer formation step); a step of mounting the electronic components 19 on the bonding layers 420 (mounting step); a step of bonding the electronic components 19 by melting the bonding layers 420 by reflow and cooling and solidifying the melted bonding layers 420 (bonding step). Factors that cause a decrease in the reliability of the electronic device A10 include defects of the bonding layers 42, which may be voids formed in the bonding layers 42. According to the research by the present inventors, the following was found regarding the formation of voids in the bonding layers 42. That is, in the manufacturing method of the electronic device A10, performing the barrier layer formation step and the plating layer formation step can suppress the formation of voids in the bonding layers 42 after the bonding step as compared to when the barrier layer formation step and the plating layer formation step are not performed (i.e., the bonding layers 420 are formed directly on the wiring layer 30). Thus, the manufacturing method of the electronic device A10 can suppress the formation of voids in the bonding layers 42, thereby suppressing defects of the bonding layers 42. In other words, according to the manufacturing method of the present embodiment, the electronic device A10 can be manufactured while suppressing defects of the bonding layers 42 and suppressing a decrease in reliability.

In the manufacturing method described above, the bonding layers 420 and the plating layers 351 are fused together in the bonding step. As a result, the electronic device A10 manufactured will have a configuration where the electronic components 19 are bonded to the wiring layer 30 via the bonding layers 42 (the bonding layers 420 and the plating layers 351) and the barrier metals 35 (the barrier layers 350). Thus, the electronic device A10 can suppress the formation of voids in the bonding layers 42 and suppress defects of the bonding layers 42. In other words, the electronic device A10 of the present disclosure can suppress defects of the bonding layers 42, thereby suppressing a decrease in reliability.

In the manufacturing method of the electronic device A10, the bonding layers 420 are formed by screen printing. This configuration can ensure sufficient thickness for the bonding layers 42 formed from the bonding layers 420. The electronic device A10 according to the present disclosure can ensure appropriate thickness for each bonding layer 42, and thus can avoid insufficient thickness of each bonding layer 42. In other words, the electronic device A10 can suppress a decrease in the bonding strength of the electronic components 19, and thus can suppress a decrease in reliability.

The electronic device A10 includes the sealing resin 6 that covers the electronic components 19. When the sealing resin 6 is formed to seal the electronic components 19 as described above, voids that may be present in the bonding layers 42 cause the sealing resin 6 to flow into the voids. As a result, the scaling resin 6 formed in the voids reduces the bonding strength of each electronic component 19, and also causes a decrease in the electrical conductivity between each electronic component 19 and the wiring layer 30. Thus, in the electronic device A10 that includes the sealing resin 6, suppressing the formation of voids in the bonding layers 42 is particularly desirable for suppressing a decrease in reliability.

In the electronic device A10, each of the electronic components 19 has a side surface 190a and a side electrode 191a. Each of the bonding layers 42 includes a fillet portion 421 in contact with a corresponding side electrode 191a. This configuration can improve the bonding strength of the electronic components 19 through the bonding layers 42. In other words, the electronic device A10 can suppress a decrease in reliability.

In the electronic device A10, the support member 2 contains a resin material, and the resin material is the same as the sealing resin 6. This configuration can reduce the difference between the coefficient of linear expansion of the support member 2 and the coefficient of linear expansion of the sealing resin 6, which makes it possible to suppress the thermal stress generated in the electronic device A10.

The following describes other embodiments and variations of the electronic device according to the present disclosure. The configurations of the elements in each of the embodiments and the variations can be combined as appropriate as long as the combination does not cause technical contradictions.

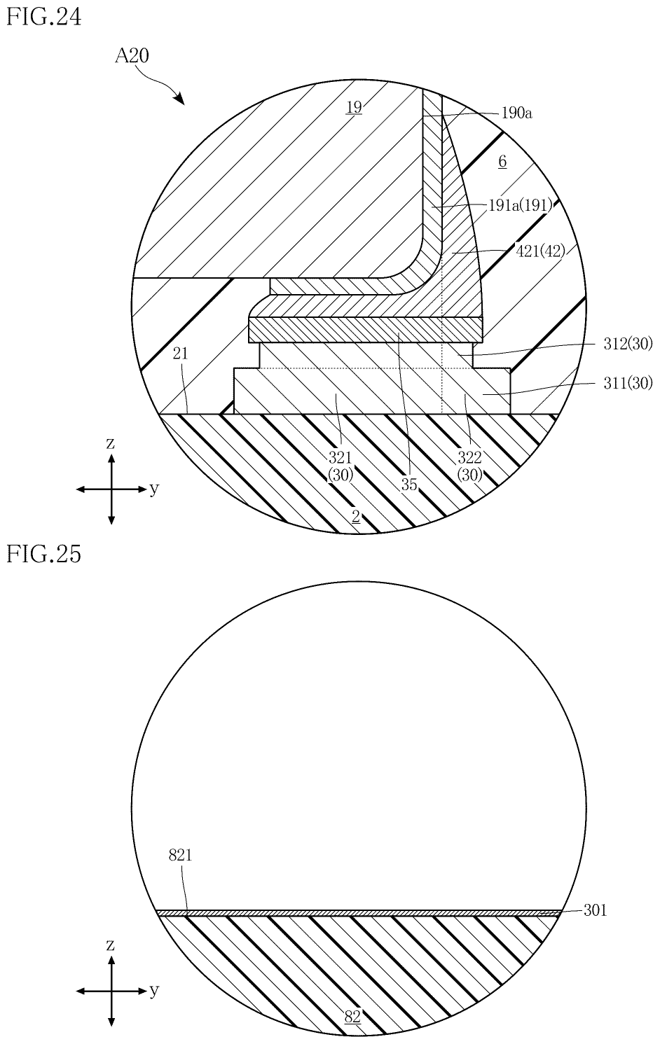

FIG. 24 shows an electronic device A20 according to a second embodiment. The cross section shown in FIG. 24 corresponds to the cross section of the electronic device A10 shown in FIG. 8. The electronic device A20 is different from the electronic device A10 in that the wiring layer 30 is formed with a portion protruding in the thickness direction z.

In the electronic device A20, the wiring layer 30 includes a body portion 311 and a pedestal portion 312. The body portion 311 corresponds to the wiring layer 30 in the electronic device A10. The pedestal portion 312 protrudes from the body portion 311 to a side (upward) in the thickness direction z. The shape of the pedestal portion 312 in plan view is not particularly limited, but may be a rectangle. As can be understood from FIG. 24, the pedestal portion 312 is smaller than a barrier metal 35 in plan view.

FIGS. 25 to 30 each show a step of a method for manufacturing the electronic device A20. The steps shown in FIGS. 25 to 30 correspond to the step of forming the wiring layer 30 (scc FIG. 15) and a step of forming the barrier layers 350 and the plating layers 351 (see FIG. 16) in the method of the electronic device A10. The other steps are the same as those for the electronic device A10.

In the manufacturing method of the electronic device A20, the columnar portions 51 and the first resin layer 82 are formed on the support substrate 80 in the same manner as in the manufacturing method of the electronic device A10, and then, as shown in FIG. 25, a seed layer 301 is formed over the entirety of the obverse surface 821 of the first resin layer 82. The seed layer 301 may be made of a Ti layer and a Cu layer stacked in this order. The seed layer 301 may be formed by sputtering.

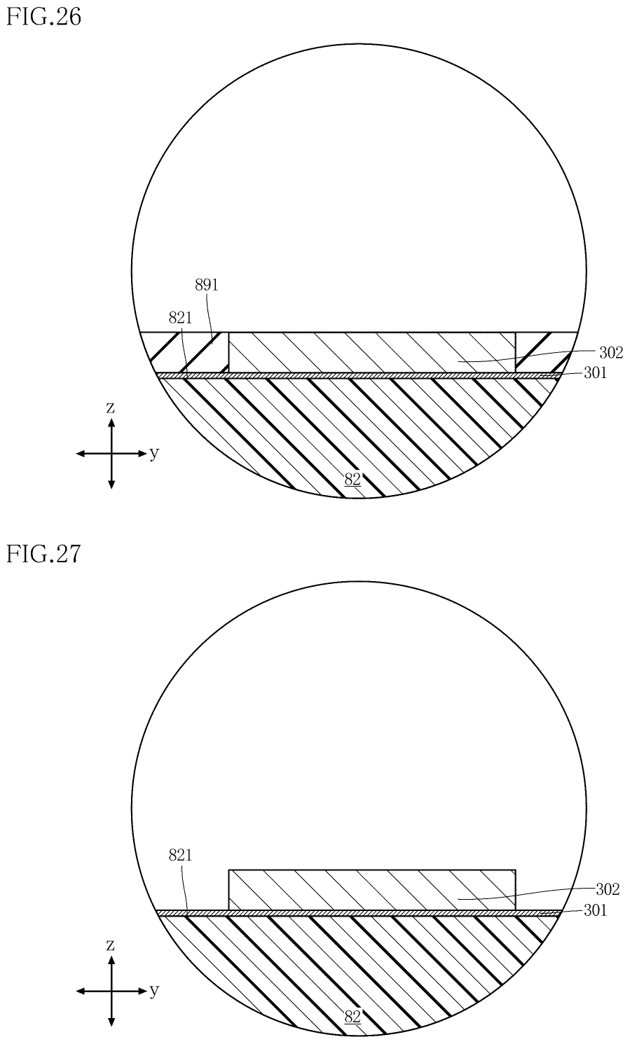

Next, as shown in FIGS. 26 and 27, a metal layer 302 is formed. As shown in FIG. 26, in the formation of the metal layer 302, a resist 891 for forming the metal layer 302 is first patterned by photolithography. Then, the metal layer 302 is formed by electroplating with the seed layer 301 serving as a conductive path. Next, as shown in FIG. 27, the resist 891 is removed. The method for removing the resist 891 is not particularly limited. As a result, the metal layer 302 is formed. As shown in FIG. 27, the seed layer 301 remains in place after the formation of the metal layer 302, and is not removed at this stage. The formation of the seed layer 301 and the formation of the metal layer 302 correspond to the step of forming the wiring layer 30 in the manufacturing method of the electronic device A10.

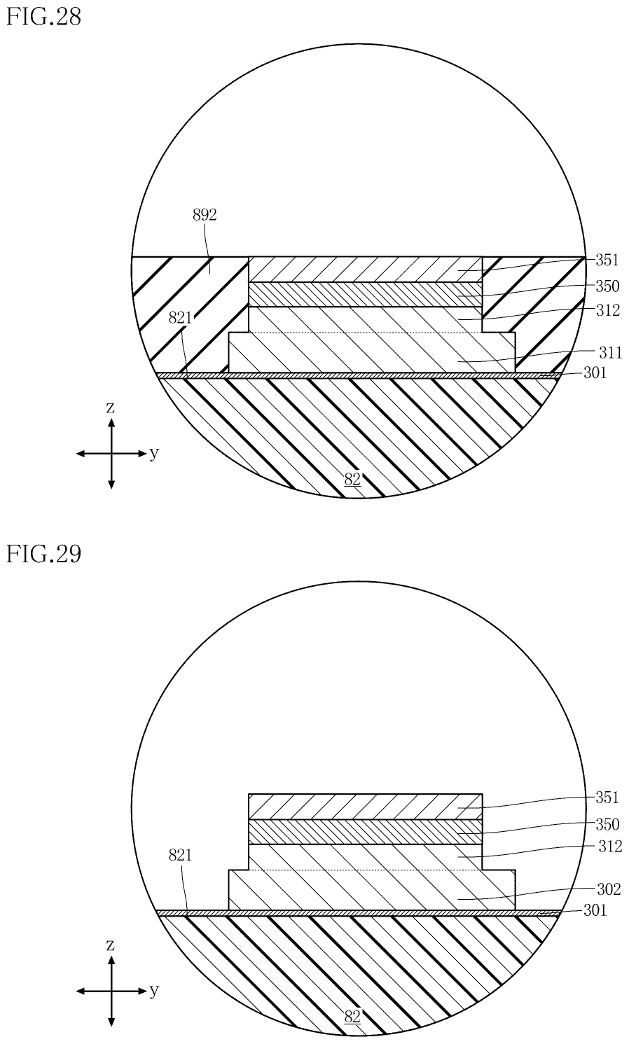

Next, as shown in FIGS. 28 and 29, a pedestal portion 312, a barrier layer 350, and a plating layer 351 are stacked in this order on the metal layer 302. Specifically, as shown in FIG. 28, a resist 892 for forming the pedestal portion 312, the barrier layer 350, and the plating layer 351 is first patterned by photolithography. Then, the pedestal portion 312, the barrier layer 350, and the plating layer 351 are formed in this order by electroplating with the seed layer 301 serving as a conductive path. The pedestal portion 312 contains Cu, the barrier layer 350 contains Ni, and the plating layer 351 contains an Sn alloy (e.g., Sn—Ag alloy). Note that the resist 892 may be provided separately when each of the pedestal portion 312, the barrier layer 350, and the plating layer 351 is formed. Next, as shown in FIG. 29, the resist 892 is removed. The method for removing the resist 892 is not particularly limited. As a result, the pedestal portion 312, the barrier layer 350, and the plating layer 351 are formed. Immediately after the resist 892 is removed, the pedestal portion 312, the barrier layer 350, and the plating layer 351 completely overlap with each other in plan view, as shown in FIG. 29. As shown in FIG. 29, the seed layer 301 remains in place without being removed.

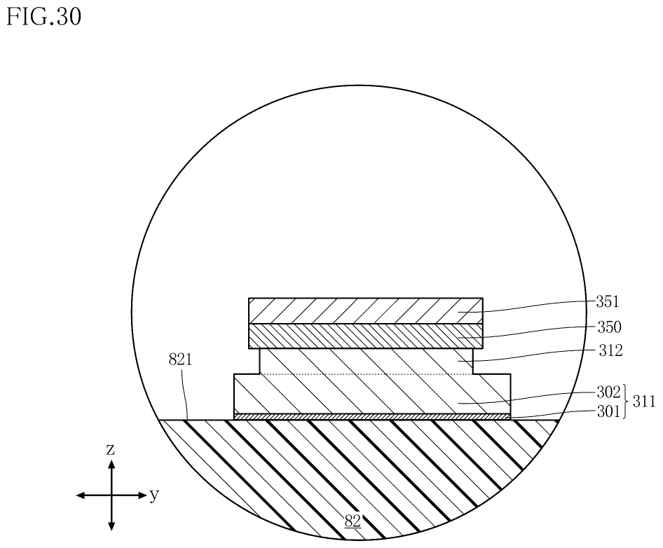

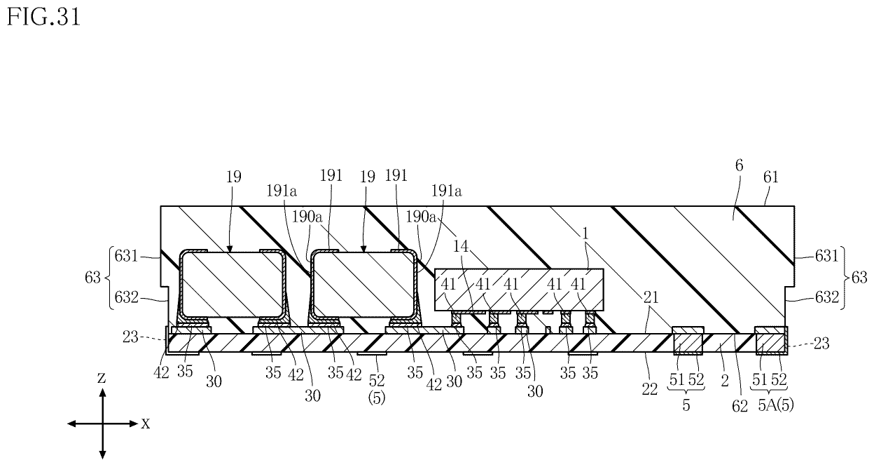

Next, as shown in FIG. 30, a part of the seed layer 301 exposed from the metal layer 302 is removed. The seed layer 301 may be removed by etching, for example. Etching solution used for the removal of the seed layer 301 may be a mixture of H₂SO₄ and H₂O₂. The etching solution reacts with the pedestal portion 312 as well as the seed layer 301, causing the pedestal portion 312 to be slightly eroded from a side surface exposed from the barrier layer 350. Thus, as can be understood from FIG. 30, the pedestal portion 312 is smaller than the barrier layer 350 in plan view. The removal of the part of the seed layer 301 exposed from the metal layer 302 allows the formation of the body portion 311 that includes the metal layer 302 and the seed layer 301 covered by the metal layer 302.

After the removal of the part of the seed layer 301, the steps from the formation of the bonding layer 420 onward (see FIGS. 17 to 23) are performed in the same manner as in the manufacturing method of the electronic device A10. The electronic device A20 is manufactured through the steps as described above.

As with the electronic device A10, the electronic device A20 can suppress the wetting and spreading of the bonding layers 42 along the wiring layer 30 with the use of the barrier metals 35, which makes it possible to avoid insufficient thickness of each bonding layer 42. In other words, as with the electronic device A10, the electronic device A20 can suppress a decrease in the bonding strength of the electronic components 19, and thus can suppress a decrease in reliability.

Additionally, the electronic device A20 and the manufacturing method thereof have the same configurations as the electronic device A10 and the manufacturing method thereof, and therefore achieve the same advantages as those achieved by electronic device A10 and the manufacturing method thereof. For example, as with the manufacturing method of the electronic device A10, the manufacturing method of the electronic device A20 also includes the barrier layer formation step and the plating layer formation step. This makes it possible to suppress the formation of voids in the bonding layers 42, thereby suppressing defects of the bonding layers 42. In other words, according to the manufacturing method of the present embodiment, the electronic device A20 can be manufactured while suppressing a decrease in reliability. In addition, as with the electronic device A10, the electronic device A20 is configured such that each of the electronic components 19 is bonded to the wiring layer 30 via a bonding layer 42 and a barrier metal 35 (a barrier layer 350). In other words, the electronic device A20 can suppress defects of the bonding layers 42 (voids introduced into the bonding layers 42), thereby suppressing a decrease in reliability.

In the electronic device A20, the wiring layer 30 includes the body portion 311 and the pedestal portion 312. The barrier metal 35 protrudes outward from the pedestal portion 312 in plan view. With this configuration, the step height between the barrier metal 35 and the body portion 311 is increased. As such, the electronic device A20 can further reduce the contact area between the bonding layer 42 and the wiring layer 30, and thus can suppress a decrease in reliability.

In each of the electronic devices A10 and A20 according to the first and second embodiments, the sealing resin 6 may have a step at each resin side surface 63. FIG. 31 shows an electronic device according to such a variation, which is an example where the variation is applied to the electronic device A10 according to the first embodiment. Although FIG. 31 shows an example where the variation is applied to the electronic device A10 according to the first embodiment, the variation can instead be applied to the electronic device A20 according to the second embodiment.

In the electronic device shown in FIG. 31, each of the resin side surfaces 63 has a first side portion 631 and a second side portion 632. In each of the resin side surfaces 63, the first side portion 631 and the second side portion 632 face in the same direction. The first side portion 631 is located outward relative to the second side portion 632 in plan view. The first side portion 631 is connected to the resin obverse surface 61, and the second side portion 632 is connected to a corresponding one of the side surfaces 23. The second side portion 632 is flush with the corresponding side surface 23. With this configuration, each of the resin side surfaces 63 has a step. In the electronic device shown in FIG. 31, the terminals 5 include a terminal 5A whose columnar portion 51 is exposed from a side surface 23. The external electrode portion 52 of the terminal 5A covers surfaces of the columnar portion 51, namely the surface exposed from the reverse surface 22 of the support member 2 and the surface exposed from the side surface 23 of the support member 2.

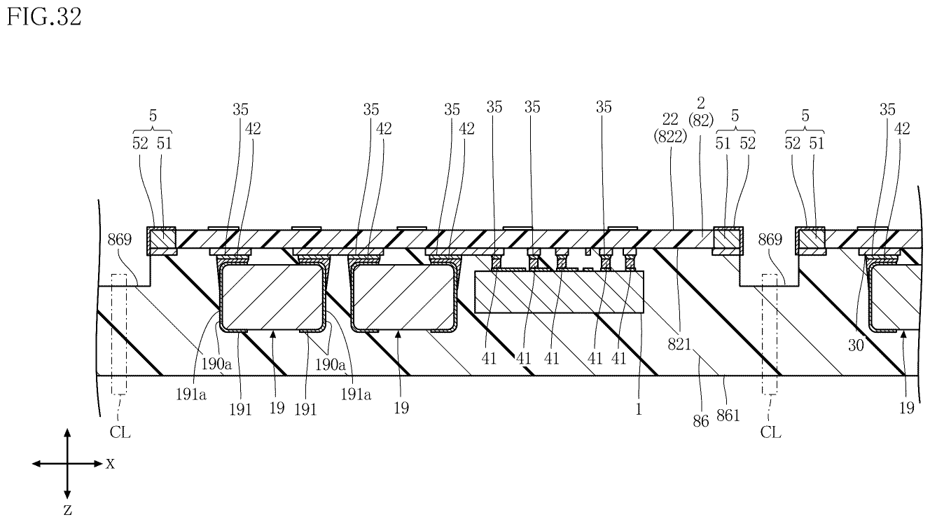

FIG. 32 shows a step of a method for manufacturing the electronic device shown in FIG. 31. The manufacturing method of the electronic device shown in FIG. 31 is the same as the manufacturing method of the electronic device A10 up to the step of removing the support substrate 80. FIG. 32 shows a step following the step of removing the support substrate 80. In the manufacturing method according to the present variation, a plurality of grooves 869 that extend from the first resin layer 82 to the second resin layer 86 are formed after the support substrate 80 is removed, as shown in FIG. 32. The grooves 869 are formed by half-cutting with a dicing blade, for example. Since the grooves 869 are formed, the support member 2 is divided for each semiconductor element 1, and the side surfaces of the support member 2 are exposed at the grooves 869. Next, electroless plating is performed to form external electrode portions 52 such that each of the external electrode portions 52 covers the surface of a columnar portion 51 exposed from the reverse surface 22 and the surface of the columnar portion 51 exposed at a groove 869. Subsequently, the second resin layer 86 is cut along cut lines CL shown in FIG. 32, whereby the second resin layer 86 is divided into individual pieces. As shown in FIG. 32, the cut lines CL pass through the respective grooves 869. As with the electronic device A10, the cutting of the second resin layer 86 is performed by a dicing process with a dicing blade, and the dicing blade is thinner than a dicing blade used in the formation (half-cutting) of the grooves 869 described above. The electronic device shown in FIG. 31 is manufactured through the steps as described above.

The electronic device shown in FIG. 31 also has the same advantages as the electronic device A10. In addition, the electronic device shown in FIG. 31 includes the terminal 5A whose external electrode portion 52 is also formed on the surface of the columnar portion 51 exposed from a side surface 23. According to this configuration, when the electronic device shown in FIG. 31 is mounted onto the wiring board of an electronic apparatus or the like, a fillet can be formed in a conductive bonding material (e.g., solder) used for the mounting. Thus, the electronic device shown in FIG. 31 facilitates visual inspection to determine whether the electronic device is appropriately bonded to the wiring board of an electronic apparatus or the like.

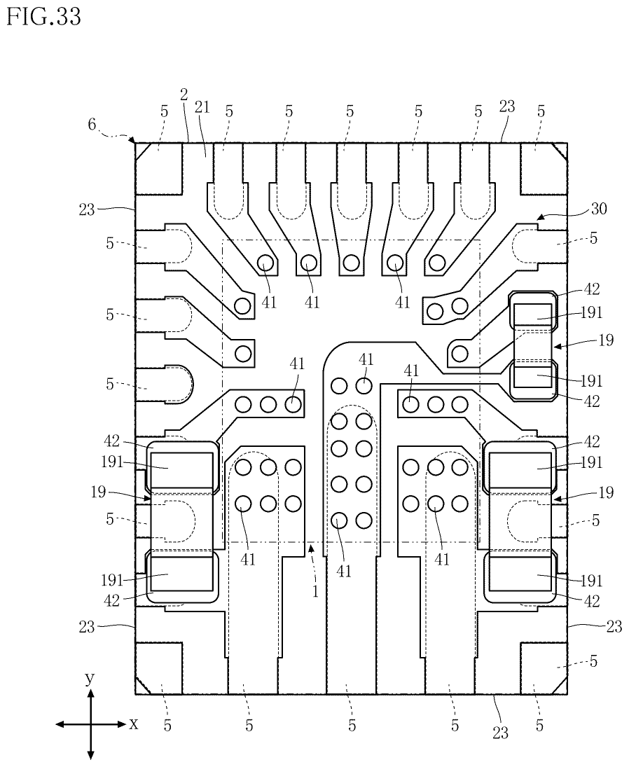

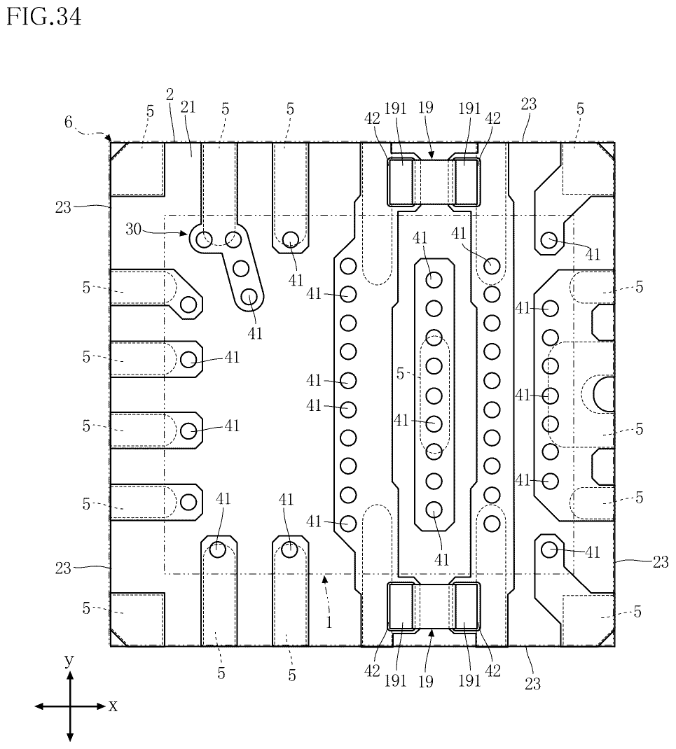

In the electronic device of the present disclosure, the number and arrangement of semiconductor elements 1 and electronic components 19, the pattern of the wiring layer 30, and the number and arrangement of terminals 5 are not limited to the illustrated examples. For example, the electronic device of the present disclosure may have any of the configurations shown in FIGS. 33 and 34. Each of the electronic devices shown in FIGS. 33 and 34 is different from the electronic device A10 in, for example, the number and arrangement of electronic components 19, the layout of the wiring layer 30, and the number and arrangement of terminals 5. As can be understood from these variations, the planar layout of the electronic device according to the present disclosure is not limited to the example shown in FIG. 2, and various other planar layouts are possible.

The electronic device of the present disclosure is not limited to the configuration with the semiconductor element 1 as a functional element, as long as the electronic device includes at least one electronic component 19. For example, the electronic device of the present disclosure may be a discrete device that includes only one electronic component 19.

The electronic device and the manufacturing method thereof according to the present disclosure are not limited to the above embodiments. Various design changes can be made to the specific configurations of the elements of the electronic device according to the present disclosure, and to the specific processes in the operations in the manufacturing method of the electronic device according to the present disclosure. For example, the present disclosure includes the embodiments described in the following clauses.
Clause 1. An electronic device comprising:
   a support member including an obverse surface facing a side in a thickness direction;
   a wiring layer formed on the obverse surface;
   a barrier metal formed on the wiring layer;
   a bonding layer formed on the barrier metal; and
   an electronic component bonded to the wiring layer via the bonding layer and the barrier metal and electrically connected to the wiring layer,
   wherein the barrier metal and the wiring layer contain mutually different metals, and
   the barrier metal is smaller than the wiring layer as viewed in the thickness direction.
Clause 2. The electronic device according to clause 1, wherein the wiring layer protrudes outward from the barrier metal as viewed in the thickness direction.
Clause 3. The electronic device according to clause 1 or 2, wherein the wiring layer includes a body portion and a pedestal portion that protrudes from the body portion to the side in the thickness direction, and
   the barrier metal protrudes outward from the pedestal portion as viewed in the thickness direction.
Clause 4. The electronic device according to any of clauses 1 to 3, wherein the electronic component includes a side surface facing in a perpendicular direction that is a direction perpendicular to the thickness direction and a side electrode formed on the side surface.
Clause 5. The electronic device according to clause 4, wherein the bonding layer includes a fillet portion in contact with the side electrode.
Clause 6. The electronic device according to any of clauses 1 to 5, wherein the barrier metal contains nickel, and the wiring layer contains copper.
Clause 7. The electronic device according to any of clauses 1 to 6, wherein the wiring layer includes an intervening portion interposed between the support member and the electronic component in the thickness direction, and an extending portion connected to the intervening portion and located outside the electronic component as viewed in the thickness direction.
Clause 8. The electronic device according to any of clauses 1 to 7, further comprising a sealing resin that covers the electronic component.
Clause 9. A method for manufacturing an electronic device, comprising:
   a step of preparing a support member including an obverse surface facing a side in a thickness direction;
   a wiring layer formation step of forming a wiring layer on the obverse surface;
   a barrier layer formation step of forming a barrier layer on the wiring layer;
   a plating layer formation step of forming a plating layer on the barrier layer;
   a bonding layer formation step of forming a bonding layer on the plating layer;
   a mounting step of mounting an electronic component on the bonding layer; and
   a bonding step of bonding the electronic component by melting the bonding layer by reflow and cooling and solidifying the melted bonding layer,
   wherein the plating layer contains tin and silver.
Clause 10. The method according to clause 9, wherein the wiring layer includes a body portion formed on the obverse surface, and a pedestal portion that protrudes from the body portion to the side in the thickness direction, and
   in the barrier layer formation step, the barrier layer is formed on the pedestal portion.
Clause 11. The method according to clause 10, wherein the wiring layer formation step includes a first process of forming a seed layer on the obverse surface, a second process of forming a metal layer on a part of the seed layer by electroplating with the seed layer serving as a conductive path, and a third process of forming the pedestal portion on a part of the metal layer, and
   the body portion has a laminated structure in which the part of the seed layer and the metal layer are stacked on each other.
Clause 12. The method according to clause 11, further comprising an etching step of performing etching after the plating layer formation step and before the bonding layer formation step,
   wherein in the etching step, a part of the seed layer exposed from the metal layer is removed.
Clause 13. The method according to any of clauses 9 to 12, wherein the barrier layer and the wiring layer contain mutually different metals.
Clause 14. The method according to clause 13, wherein the barrier layer contains nickel, and
   the wiring layer contains copper.
Clause 15. The method according to any of clauses 9 to 14, wherein in the barrier layer formation step, the barrier layer is formed to be smaller than the wiring layer as viewed in the thickness direction.
Clause 16. The method according to any of clauses 9 to 15, wherein in the bonding layer formation step, the bonding layer is formed by screen printing with solder paste.
Clause 17. The method according to any of clauses 9 to 16, wherein the electronic component includes side electrodes disposed on respective ends in a perpendicular direction that is a direction perpendicular to the thickness direction, and
   the bonding layer has a fillet formed in contact with one of the side electrodes by the bonding step.
Clause 18. The method according to any of clauses 9 to 17, further comprising a step of forming a sealing resin covering the electronic component.

REFERENCE NUMERALS

| | | |
|---|---|---|
| A10, A20: Electronic device | 1: Semiconductor element | 10a: Element obverse surface |
| 10b: Element reverse surface | 11: Body portion | 12: Pad |
| 13: Insulating film | 14: Redistribution wiring | 19: Electronic component |
| 190a: Side surface | 191: Terminal | 191a: Side electrode |
| 2: Support member | 21: Obverse surface | 22: Reverse surface |
| 23: Side surface | 30: Wiring layer | 301: Seed layer |
| 302: Metal layer | 311: Body portion | 312: Pedestal portion |
| 321: Intervening portion | 322: Extending portion | 35: Barrier metal |
| 350: Barrier layer | 351: Plating layer | 41, 410: Bonding layer |
| 42, 420: Bonding layer | 421: Fillet portion | 5: Terminal |
| 5A: Terminal | 51: Columnar portion | 52: External electrode portion |
| 6: Sealing resin | 61: Resin obverse surface | 62: Resin reverse surface |
| 63: Resin side surface | 631: First side portion | 632: Second side portion |
| 80: Support substrate | 80a: Substrate obverse surface | 80b: Substrate reverse surface |
| 82: First resin layer | 821: Obverse surface | 822: Bottom surface |
| 851: Columnar conductor | 86: Second resin layer | 861: Top surface |
| 869: Groove | 891, 892: Resist | CL: Cut line |

1. An electronic device comprising:
a support member including an obverse surface facing a side in a thickness direction;
a wiring layer formed on the obverse surface;
a barrier metal formed on the wiring layer;
a bonding layer formed on the barrier metal; and
an electronic component bonded to the wiring layer via the bonding layer and the barrier metal and electrically connected to the wiring layer,
wherein the barrier metal and the wiring layer contain mutually different metals, and
the barrier metal is smaller than the wiring layer as viewed in the thickness direction.

2. The electronic device according to claim 1, wherein the wiring layer protrudes outward from the barrier metal as viewed in the thickness direction.

3. The electronic device according to claim 1, wherein the wiring layer includes a body portion and a pedestal portion that protrudes from the body portion to the side in the thickness direction, and
the barrier metal protrudes outward from the pedestal portion as viewed in the thickness direction.

4. The electronic device according to claim 1, wherein the electronic component includes a side surface facing in a perpendicular direction that is a direction perpendicular to the thickness direction and a side electrode formed on the side surface.

5. The electronic device according to claim 4, wherein the bonding layer includes a fillet portion in contact with the side electrode.

6. The electronic device according to claim 1, wherein the barrier metal contains nickel, and
the wiring layer contains copper.

7. The electronic device according to claim 1, wherein the wiring layer includes an intervening portion interposed between the support member and the electronic component in the thickness direction, and an extending portion connected to the intervening portion and located outside the electronic component as viewed in the thickness direction.

8. The electronic device according to claim 1, further comprising a sealing resin that covers the electronic component.

9. A method for manufacturing an electronic device, comprising:
a step of preparing a support member including an obverse surface facing a side in a thickness direction;
a wiring layer formation step of forming a wiring layer on the obverse surface;
a barrier layer formation step of forming a barrier layer on the wiring layer;
a plating layer formation step of forming a plating layer on the barrier layer;
a bonding layer formation step of forming a bonding layer on the plating layer;
a mounting step of mounting an electronic component on the bonding layer; and
a bonding step of bonding the electronic component by melting the bonding layer by reflow and cooling and solidifying the melted bonding layer,
wherein the plating layer contains tin and silver.

10. The method according to claim 9, wherein the wiring layer includes a body portion formed on the obverse surface, and a pedestal portion that protrudes from the body portion to the side in the thickness direction, and
in the barrier layer formation step, the barrier layer is formed on the pedestal portion.

11. The method according to claim 10, wherein the wiring layer formation step includes a first process of forming a seed layer on the obverse surface, a second process of forming a metal layer on a part of the seed layer by electroplating with the seed layer serving as a conductive path, and a third process of forming the pedestal portion on a part of the metal layer, and
the body portion has a laminated structure in which the part of the seed layer and the metal layer are stacked on each other.

12. The method according to claim 11, further comprising an etching step of performing etching after the plating layer formation step and before the bonding layer formation step, wherein in the etching step, a part of the seed layer exposed from the metal layer is removed.

13. The method according to claim 9, wherein the barrier layer and the wiring layer contain mutually different metals.

14. The method according to claim 13, wherein the barrier layer contains nickel, and
the wiring layer contains copper.

15. The method according to claim 9, wherein in the barrier layer formation step, the barrier layer is formed to be smaller than the wiring layer as viewed in the thickness direction.

16. The method according to claim 9, wherein in the bonding layer formation step, the bonding layer is formed by screen printing with solder paste.

17. The method according to claim 9, wherein the electronic component includes side electrodes disposed on respective ends in a perpendicular direction that is a direction perpendicular to the thickness direction, and
the bonding layer has a fillet formed in contact with one of the side electrodes by the bonding step.

18. The method according to claim 9, further comprising a step of forming a sealing resin covering the electronic component.
